(19) United States
(12) Patent Application Publication
(10) Pub. No.: US 2020/0251166 A1
(43) Pub. Date: Aug. 6, 2020

(54) Programmable Memory Cell with a Feedback Signal for Programming the Programmable Memory Cell

(71) Applicant: AGI CORPORATION, Hsinchu (TW)

(72) Inventors: SHIH-HSIU CHEN, HSINCHU (TW); WEI-FAN WU, HSINCHU (TW); HSUAN-CHI SU, HSINCHU (TW); WEI HUAN CHEN, HSINCHU (TW); CHING-HSIANG LIN, HSINCHU (TW); YUNG-CHIEN LEE, HSINCHU (TW); SHUI-SHOU WANG, HSINCHU (TW); WEN-HUA YU, HSINCHU (TW)

(21) Appl. No.: 16/388,880

(22) Filed: Apr. 19, 2019

Related U.S. Application Data
(60) Provisional application No. 62/799,759, filed on Feb. 1, 2019.

(51) Int. Cl. G11C 13/00; G11C 17/16; G11C 17/12

(52) U.S. Cl. CPC G11C 13/0069; G11C 13/0026; G11C 2013/0078; G11C 17/165; G11C 17/12; G11C 13/0038

(57) ABSTRACT

A circuit to program a programmable memory cell, such as an OTP (One-Time-Programmable) memory cell, by using a current source to output a current to a bit-line of the OTP memory cell, wherein the amount of the current outputted from the current source can be adjusted according to a feedback signal from the OTP memory cell.

### CROSS-REFERENCES TO RELATED APPLICATIONS

This application claims the benefit of U.S. Provisional Patent Application No. 62/799,759 filed on Feb. 1, 2019, which is hereby incorporated by reference herein and made a part of the specification.

### BACKGROUND OF THE INVENTION

### I. Field of the Invention

The invention relates to a programmable memory cell and, in particular, but not exclusively, to a programmable memory cell with feedback signal for programming the programmable memory cell.

### II. Description of the Prior Art

Conventional methods to program a programmable memory cell such as an OTP (One-Time-Programmable) memory cell utilize a current source to generate a constant current to a bit-line of the OTP memory cell. In such methods, there is no feedback signal from the OTP memory cell to indicate the current status of the fuse element inside the OTP memory cell. As a result, the fuse element of the OTP memory cell can potentially explode and damage the circuits surrounding the fuse element when the fuse element is overheated for a certain amount of time.

Therefore, a better solution is needed to resolve the above-mentioned issue.

### SUMMARY OF THE INVENTION

One objective of the present invention is to provide a circuit to program a programmable memory cell by using a current source to output a current to a bit-line of the programmable memory cell, wherein the amount of the current outputted from the current source can be adjusted according to a feedback signal from the programmable memory cell.

One objective of the present invention is to provide a circuit to program an OTP (One-Time-Programmable) memory cell by using a current source to output a current to a bit-line of the OTP memory cell, wherein the amount of the current can be adjusted according to a feedback signal from the OTP memory cell so as to prevent a fuse element of the OTP memory cell from exploding and damaging the circuits surrounding the fuse element.

One objective of the present invention is to provide a circuit to program a programmable resistive memory cell by using a current source to output a current to a bit-line of the programmable resistive memory cell, wherein the amount of the current can be adjusted according to a feedback signal from the programmable resistive memory cell.

In one embodiment of the present invention, a circuit is disclosed, wherein the circuit comprises: an OTP memory cell, wherein the OTP memory cell comprises a fuse element and a field-effect transistor (FET), wherein a bit line of the OTP memory cell and the channel path of the field-effect transistor (FET) are electrically connected via the fuse element; a bias unit, for supplying a bias voltage to a current source that is electrically coupled to the bit line of the OTP memory cell; and a control unit, for receiving a feedback voltage capable of indicating a voltage change across the fuse element of the OTP memory cell, wherein when programming the OTP memory cell, the bias voltage is adjusted according to the received feedback voltage.

In one embodiment of the present invention, a circuit is disclosed, wherein the circuit comprises: an OTP memory cell, wherein the OTP memory cell comprises a fuse element and a field-effect transistor (FET), wherein a bit line of the OTP memory cell and the channel path of the field-effect transistor (FET) are electrically connected via the fuse element; a bias unit, for supplying a bias current to a voltage source that is electrically coupled to the bit line of the OTP memory cell; and a control unit, for receiving a feedback current capable of indicating a current flowing through the fuse element of the OTP memory cell, wherein when programming the OTP memory cell, the bias current is adjusted according to the received feedback current.

In one embodiment of the present invention, a circuit is disclosed, wherein the circuit comprises: a programmable resistive memory cell, wherein the programmable resistive memory cell comprises a programmable resistive element and a field-effect transistor (FET), wherein a bit line of the programmable resistive memory cell and the channel path of the field-effect transistor (FET) are electrically connected via the programmable resistive element; a bias unit, for supplying a bias voltage to a current source that is electrically coupled to the bit line of the programmable resistive memory cell; and a control unit, for receiving a feedback voltage capable of indicating a voltage change across the programmable resistive element of the programmable resistive memory cell, wherein when programming the programmable resistive memory cell, the bias voltage is adjusted according to the received feedback voltage.

In one embodiment of the present invention, a circuit is disclosed, wherein the circuit comprises: a programmable resistive memory cell, wherein the programmable resistive memory cell comprises a programmable resistive element and a field-effect transistor (FET), wherein a bit line of the programmable resistive memory cell and the channel path of the field-effect transistor (FET) are electrically connected via the programmable resistive element; a bias unit, for supplying a bias current to a voltage source that is electrically coupled to the bit line of the programmable resistive memory cell; and a control unit, for receiving a feedback current capable of indicating a current flowing through the programmable resistive element of the programmable resistive memory cell, wherein when programming the programmable resistive memory cell, the bias current is adjusted according to the received feedback current.

In one embodiment of the present invention, a method to program an OTP memory cell is disclosed, wherein the method comprises using a current source to output a current to a bit-line of the OTP memory cell, wherein the amount of the current can be adjusted according to a feedback signal from the OTP memory cell so as to prevent a fuse element of the OTP memory cell from exploding and damaging the circuits surrounding the fuse element.

In one embodiment of the present invention, a method to program an OTP memory cell is disclosed, wherein the method comprises using a voltage source to output a voltage to a bit-line of the OTP memory cell, wherein the level of the voltage can be adjusted according to a feedback signal from the OTP memory cell so as to prevent a fuse element of the OTP memory cell from exploding and damaging the circuits surrounding the fuse element.

In one embodiment of the present invention, a method to program a programmable resistive memory cell is disclosed, wherein the method comprises using a current source to output a current to a bit-line of the programmable resistive memory cell, wherein the amount of the current can be adjusted according to a feedback signal from the programmable resistive memory cell.

In one embodiment of the present invention, a method to program a programmable resistive memory cell is disclosed, wherein the method comprises using a voltage source to output a voltage to a bit-line of the programmable resistive memory cell, wherein the level of the voltage can be adjusted according to a feedback signal from the programmable resistive memory cell.

The detailed technology and above preferred embodiments implemented for the present invention are described in the following paragraphs accompanying the appended drawings for people skilled in this field to well appreciate the features of the claimed invention.

### BRIEF DESCRIPTION OF DRAWINGS

The foregoing aspects and many of the accompanying advantages of this invention will become more readily appreciated as the same becomes better understood by reference to the following detailed description when taken in conjunction with the accompanying drawings, wherein:

FIG. 1A illustrates a circuit comprising an OTP memory cell with a feedback voltage for programming the OTP memory cell in accordance with one embodiment of the present invention;

FIG. 1B illustrates a circuit comprising an OTP memory cell with a feedback current for programming the OTP memory cell in accordance with one embodiment of the present invention;

FIG. 2A illustrates a circuit comprising a programmable resistive memory cell with a feedback voltage for programming the programmable resistive memory cell in accordance with one embodiment of the present invention; and

FIG. 2B illustrates a circuit comprising a programmable resistive memory cell with a feedback current for programming the programmable resistive memory cell in accordance with one embodiment of the present invention;

### DETAILED DESCRIPTION OF EMBODIMENT

The detailed explanation of the present invention is described as following. The described preferred embodiments are presented for purposes of illustrations and description, and they are not intended to limit the scope of the present invention.

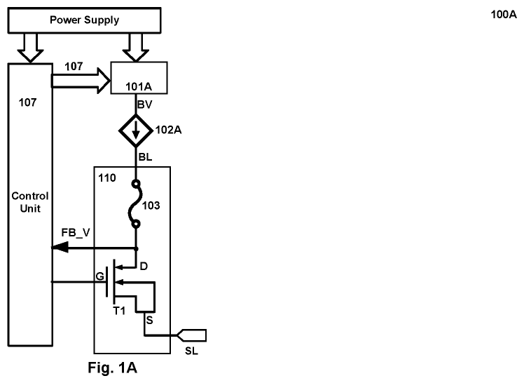

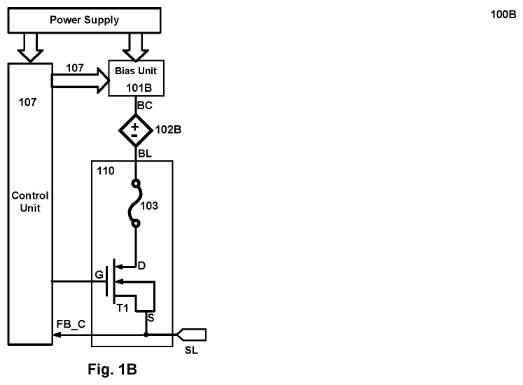

FIG. 1A illustrates a circuit comprising an OTP memory cell with a feedback voltage for programming the OTP memory cell in accordance with one embodiment of the present invention. As shown in FIG. 1A, the circuit comprises an OTP memory cell 110 wherein OTP memory cell 110 comprises a fuse element 103 and a field-effect transistor (FET) T1, wherein a bit line BL of the OTP memory cell 110 and the channel path of the field-effect transistor (FET) T1 are electrically connected via the fuse element 103; a bias unit 101A, for supplying a bias voltage BV to a current source 101A that is electrically coupled to the bit line BL of the OTP memory cell 110; and a control unit 107, for receiving a feedback voltage FB_V capable of indicating a voltage change across the fuse element 103, wherein when programming the OTP memory cell 110, the bias voltage BV is adjusted according to the received feedback voltage FB_V. The received feedback voltage FB_V can indicate a voltage change across the fuse element 103 while programming the OTP memory cell 110 due to the resistance of the fuse element 103 will vary while programming the OTP memory cell 110.

In one embodiment, the fuse element 103 is an e-fuse (electrical fuse).

In one embodiment, the fuse element 103 is an antifuse.

In one embodiment, the OTP memory cell is formed by a CMOS process.

In one embodiment, the field-effect transistor (FET) T1 is an N-channel field-effect transistor, wherein the drain terminal D of the field-effect transistor (FET) T1 is coupled to the fuse element 103, the drain terminal S of the field-effect transistor (FET) T1 is coupled to the source line SL of the OTP memory cell 110, and the gate terminal G of the field-effect transistor (FET) T1 is coupled to the control unit 107.

In one embodiment, the field-effect transistor (FET) T1 can be a P-channel field-effect transistor.

In one embodiment, the control unit 107 comprises a voltage comparator to determine whether the feedback voltage FB_V has reached a predetermined threshold voltage, and the control unit 107 decreases or cuts off the bias voltage BV to the current source 101A by using at least one control signal 107A.

In one embodiment, the bias unit 101A comprises a digital to analog converter for generating the bias voltage BV.

In one embodiment, the bias unit 101A comprises a plurality of reference voltages that can be selected for generating the bias voltage BV.

In one embodiment, the control unit 107 comprises an analog-to-digital converter (ADC) to convert the feedback voltage FB_V to binary bits, wherein the control unit 107 decreases or cuts off the bias voltage BV by using at least one control signal 107A, when the binary bits has reached a predetermined threshold value.

In one embodiment, the control unit 107 comprises a microprocessor to control or manage the analog-to-digital converter (ADC). In one embodiment, the control unit 107 comprises a mapping table, wherein the binary bits are mapped to a corresponding bias voltage BV of the bias unit 101A.

In one embodiment, the control unit 107 can be entirely implemented in hardware.

FIG. 1B illustrates a circuit comprising an OTP memory cell with a feedback voltage for programming the OTP memory cell in accordance with one embodiment of the present invention. As shown in FIG. 1B, the circuit comprises an OTP memory cell 110 wherein OTP memory cell 110 comprises a fuse element 103 and a field-effect transistor (FET) T1, wherein a bit line BL of the OTP memory cell 110 and the channel path of the field-effect transistor (FET) T1 are electrically connected via the fuse element 103; a bias unit 101B, for supplying a bias current BC to a voltage source 101B that is electrically coupled to the bit line BL of the OTP memory cell 110; and a control unit 107, for receiving a feedback current FB_C capable of indicating a voltage change across the fuse element 103, wherein when programming the OTP memory cell 110, the bias current BC is adjusted according to the received feedback current FB_C.

In one embodiment, the bias unit 101B comprises a digital to analog converter for generating the bias current BC.

In one embodiment, the bias unit 101B comprises a plurality of current sources that can be selected for generating the current BC.

In one embodiment, the fuse element 103 is an e-fuse (electrical fuse).

In one embodiment, the fuse element 103 is an antifuse.

In one embodiment, the OTP memory cell is formed by a CMOS process.

In one embodiment, the field-effect transistor (FET) T1 is an N-channel field-effect transistor, wherein the drain terminal D of the field-effect transistor (FET) T1 is coupled to the fuse element 103, the drain terminal S of the field-effect transistor (FET) T1 is coupled to the source line SL of the OTP memory cell 110, and the gate terminal G of the field-effect transistor (FET) T1 is coupled to the control unit 107.

In one embodiment, the field-effect transistor (FET) T1 can be a P-channel field-effect transistor.

In one embodiment, the control unit 107 comprises a current meter to determine whether the feedback current FB_C has reached a predetermined threshold current, and the control unit 107 decreases or cuts off the bias current BC by using at least one control signal 107A, when the predetermined threshold current is reached.

In one embodiment, the control unit 107 comprises current-to-voltage converter to convert the feedback current FB_C to a corresponding voltage, wherein the control unit 107 decreases or cuts off the bias voltage BV when said corresponding voltage reaches a predetermined threshold voltage.

In one embodiment, the control unit 107 comprises an analog-to-digital converter (ADC) to convert said corresponding voltage to binary bits, wherein the control unit 107 decreases or cuts off the bias current BC by using at least one control signal 107A, when the binary bits has reached a predetermined threshold value.

In one embodiment, the control unit 107 comprises a microprocessor to control or manage the analog-to-digital converter (ADC). In one embodiment, the control unit 107 comprises a mapping table, wherein the binary bits are mapped to a corresponding bias current BC of the bias unit 101B.

In one embodiment, the control unit 107 can be entirely implemented in hardware.

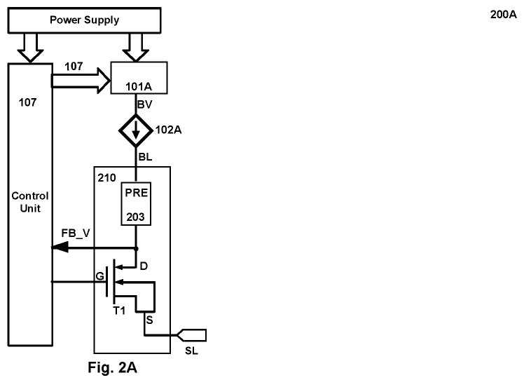

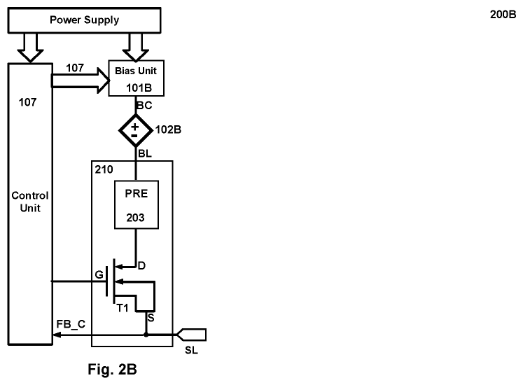

FIG. 2A illustrates a circuit comprising programmable resistive memory cell with a feedback voltage for programming the OTP memory cell in accordance with one embodiment of the present invention. As shown in FIG. 2A, the circuit comprises: a programmable resistive memory cell 210, wherein the programmable resistive memory cell 210 comprises a programmable resistive element (PRE) 203 and a field-effect transistor (FET) T1, wherein a bit line BL of the programmable resistive memory cell 210 and the channel path of the field-effect transistor (FET) T1 are electrically connected via the programmable resistive element 203; a bias unit 101A, for supplying a bias voltage BV to a current source 101A that is electrically coupled to the bit line BL of the programmable resistive memory cell 210; and a control unit 107, for receiving a feedback voltage FB_V capable of indicating a voltage change across the programmable resistive element 203, wherein when programming the programmable resistive memory cell 210, the bias voltage BV is adjusted according to the received feedback voltage FB_V.

In one embodiment, the field-effect transistor (FET) T1 is an N-channel field-effect transistor, wherein the drain terminal D of the field-effect transistor (FET) T1 is coupled to the programmable resistive element 203, the drain terminal S of the field-effect transistor (FET) T1 is coupled to the source line SL of the programmable resistive memory cell 210, and the gate terminal G of the field-effect transistor (FET) T1 is coupled to the control unit 107.

In one embodiment, the field-effect transistor (FET) T1 can be a P-channel field-effect transistor.

In one embodiment, the control unit 107 comprises a voltage comparator to determine whether the feedback voltage FB_C has reached a predetermined threshold voltage, and the control unit 107 decreases or cuts off the bias voltage BV to the current source 101A by using at least one control signal 107A.

In one embodiment, the control unit 107 comprises an analog-to-digital converter (ADC) to convert the feedback voltage FB_V to binary bits, wherein the control unit 107 decreases or cuts off the bias voltage BV by using at least one control signal 107A, when the binary bits has reached a predetermined threshold value.

In one embodiment, the control unit 107 comprises a microprocessor to control or manage the analog-to-digital converter (ADC). In one embodiment, the control unit 107 comprises a mapping table, wherein the binary bits are mapped to a corresponding bias voltage BV of the bias unit 101A.

In one embodiment, the control unit 107 can be entirely implemented in hardware.

FIG. 2B illustrates a circuit comprising programmable resistive memory cell with a feedback voltage for programming the OTP memory cell in accordance with one embodiment of the present invention. As shown in FIG. 2B, the circuit comprises: a programmable resistive memory cell 210, wherein the programmable resistive memory cell 210 comprises a programmable resistive element (PRE) 203 and a field-effect transistor (FET) T1, wherein a bit line BL of the programmable resistive memory cell 210 and the channel path of the field-effect transistor (FET) T1 are electrically connected via the programmable resistive element 203; a bias unit 102, for supplying a bias current BC to a voltage source 101B that is electrically coupled to the bit line BL of the programmable resistive memory cell 210; and a control unit 107, for receiving a feedback current FB_C capable of indicating a voltage change across the programmable resistive element 203, wherein when programming the programmable resistive memory cell 210, the bias current BC is adjusted according to the received feedback current FB_C.

In one embodiment, the field-effect transistor (FET) T1 is an N-channel field-effect transistor, wherein the drain terminal D of the field-effect transistor (FET) T1 is coupled to the programmable resistive element 203, the drain terminal S of the field-effect transistor (FET) T1 is coupled to the source line SL of the programmable resistive memory cell 210, and the gate terminal G of the field-effect transistor (FET) T1 is coupled to the control unit 107.

In one embodiment, the field-effect transistor (FET) T1 can be a P-channel field-effect transistor.

In one embodiment, the control unit 107 comprises a current meter to determine whether the feedback current FB_C has reached a predetermined threshold current, and the control unit 107 decreases or cuts off the bias current BC by using the at least one control signal 107A.

In one embodiment, the control unit 107 comprises a current-to-voltage converter to convert the feedback current FB_C to a corresponding voltage, wherein the control unit 107 decreases or cuts off the bias voltage BV when said corresponding voltage reaches a predetermined threshold voltage.

In one embodiment, the control unit 107 comprises an analog-to-digital converter (ADC) to convert said corresponding voltage to binary bits, wherein the control unit 107 decreases or cuts off the bias current BC by using at least one control signal 107A, when the binary bits has reached a predetermined threshold value.

In one embodiment, the control unit 107 comprises a microprocessor to control or manage the analog-to-digital converter (ADC). In one embodiment, the control unit 107 comprises a mapping table, wherein the binary bits are mapped to a corresponding bias current BC of the bias unit 102.

In one embodiment, the control unit 107 can be entirely implemented in hardware.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. A circuit, comprising:
an OTP memory cell, comprising a fuse element and a field-effect transistor (FET), wherein a bit line of the OTP memory cell and the channel path of the field-effect transistor (FET) are electrically connected via the fuse element;
a bias unit, for supplying a bias voltage to a current source that is electrically coupled to the bit line of the OTP memory cell; and
a control unit, for receiving a feedback voltage capable of indicating a voltage change across the fuse element of the OTP memory cell, wherein when programming the OTP memory cell, the bias voltage is adjusted according to the received feedback voltage.

2. The circuit according to claim 1, wherein the fuse element is a fuse.

3. The circuit according to claim 1, wherein the fuse element is an antifuse.

4. The circuit according to claim 1, wherein the OTP memory cell is made by a CMOS process.

5. The circuit according to claim 1, wherein the field-effect transistor (FET) is an N-channel field-effect transistor (FET).

6. The circuit according to claim 1, wherein the control unit comprises a voltage comparator to determine whether the feedback voltage has reached a predetermined threshold voltage, wherein the control unit decreases or cuts off the bias voltage to the current source when the predetermined threshold voltage is reached.

7. The circuit according to claim 1, wherein the control unit comprises an analog-to-digital converter (ADC) to convert the feedback voltage to binary bits, wherein the control unit decreases or cuts off the bias voltage when the binary bits has reached a predetermined threshold value.

8. A circuit, comprising:
an OTP memory cell, comprising a fuse element and a field-effect transistor (FET), wherein a bit line of the OTP memory cell and the channel path of the field-effect transistor (FET) are electrically connected via the fuse element;
a bias unit, for supplying a bias current to a voltage source that is electrically coupled to the bit line of the OTP memory cell; and
a control unit, for receiving a feedback current capable of indicating a current flowing through the fuse element of the OTP memory cell, wherein when programming the OTP memory cell, the bias current is adjusted according to the received feedback current.

9. The circuit according to claim 8, wherein the fuse element is a fuse.

10. The circuit according to claim 8, wherein the fuse element is an antifuse.

11. The circuit according to claim 8, wherein the OTP memory cell is made by a CMOS process.

12. The circuit according to claim 8, wherein the field-effect transistor (FET) is an N-channel field-effect transistor (FET).

13. The circuit according to claim 8, wherein the control unit comprises a current meter to determine whether the feedback current has reached a predetermined threshold current, wherein the control unit decreases or cuts off the bias current when the predetermined threshold current is reached.

14. A circuit, comprising:
a programmable resistive memory cell, comprising a programmable resistive element and a field-effect transistor (FET), wherein a bit line of the programmable resistive memory cell and the channel path of the field-effect transistor (FET) are electrically connected via the programmable resistive element;
a bias unit, for supplying a bias voltage to a current source that is electrically coupled to the bit line of the programmable resistive memory cell; and
a control unit, for receiving a feedback voltage capable of indicating a voltage change across the programmable resistive element of the programmable resistive memory cell, wherein when programming the programmable resistive memory cell, the bias voltage is adjusted according to the received feedback voltage.

15. The circuit according to claim 14, wherein the field-effect transistor (FET) is an N-channel field-effect transistor (FET).

16. The circuit according to claim 14, wherein the control unit comprises a voltage comparator to determine whether the feedback voltage has reached a predetermined threshold voltage, wherein the control unit decreases or cuts off the bias voltage to the current source when the predetermined threshold voltage is reached.

17. The circuit according to claim 14, wherein the control unit comprises an analog-to-digital converter (ADC) to convert the feedback voltage to binary bits, wherein the control unit decreases or cuts off the bias voltage when the binary bits has reached a predetermined threshold value.

18. The circuit according to claim 14, wherein the programmable resistive memory cell is made by a CMOS process.
